(19) United States
(12) Patent Application Publication
(10) Pub. No.: US 2024/0105637 A1
(43) Pub. Date: Mar. 28, 2024

(54) SEMICONDUCTOR DEVICE AND SEMICONDUCTOR MODULE, AND METHOD OF MANUFACTURING SEMICONDUCTOR DEVICE

(71) Applicant: FUJI ELECTRIC CO., LTD., Kanagawa (JP)

(72) Inventors: Yuta EBUKURO, Matsumoto-city (JP); Akio YAMANO, Matsumoto-city (JP)

(21) Appl. No.: 18/356,238

(22) Filed: Jul. 21, 2023

(30) Foreign Application Priority Data
Sep. 28, 2022 (JP) 2022-154518

(51) Int. Cl. H01L 23/544; H01L 23/00; H01L 23/31; H01L 27/06

(52) U.S. Cl. CPC H01L 23/544; H01L 23/3107; H01L 24/48; H01L 27/0635; H01L 29/7397

(57) ABSTRACT

Provided is a semiconductor device that includes one or more transistor portions and one or more diode portions provided at different positions in a top view, a semiconductor substrate provided with the one or more transistor portions and the one or more diode portions, an upper surface electrode arranged above the semiconductor substrate, and one or more first mark portions arranged upper than the upper surface electrode, each of the one or more first mark portions being arranged so as to overlap both one of the one or more transistor portions and one of the one or more diode portions in the top view, in which each of the one or more first mark portions has a concave shape or a convex shape in the top view or in a depth direction of the semiconductor substrate.

The contents of the following patent application(s) are incorporated herein by reference:
NO. 2022-154518 filed in JP on Sep. 28, 2022

### BACKGROUND

### 1. Technical Field

The present invention relates to a semiconductor device and a semiconductor module, and a method of manufacturing the semiconductor device.

### 2. Related Art

Conventionally, a semiconductor device that includes a transistor portion such as an IGBT (Insulated Gate Bipolar Transistor) and a diode portion such as an FWD (Free Wheeling Diode) is known (for example, see Patent Documents 1 to 4).

Patent Document 1: Japanese Patent Application Publication No. 2020-202250

Patent Document 2: Japanese Patent Application Republication WO2020/059285

Patent Document 3: Japanese Patent Application Publication No. 2019-201160

Patent Document 4: Japanese Patent Application Publication No. 2021-166247

### BRIEF DESCRIPTION OF THE DRAWINGS

FIG. 1 shows a top view illustrating an example of semiconductor wafer 200.

FIG. 2 shows a cross-sectional view illustrating an example of a semiconductor module 300 according to one embodiment of the present invention.

FIG. 3 illustrates an example of an upper surface structure of a semiconductor device 100-r according to a reference example.

FIG. 4 illustrates an example of an upper surface structure of a semiconductor device 100 according to one embodiment of the present invention.

FIG. 5 illustrates an arrangement example of mark portions and connecting portions 172.

FIG. 6 illustrates an example of a cross section taken along line A-A in FIG. 4.

FIG. 7 illustrates an example of a cross section taken along line B-B in FIG. 4.

FIG. 8 illustrates an example of a cross section taken along line C-C in FIG. 4.

FIG. 9 illustrates another example of the cross section taken along line C-C.

FIG. 10 illustrates another example of an upper surface structure of a semiconductor device 100.

FIG. 11 illustrates another example of an upper surface structure of a semiconductor device 100.

FIG. 12 illustrates an example of a cross section taken along line D-D in FIG. 11.

FIG. 13 illustrates another example of the cross section taken along line D-D in FIG. 11.

FIG. 14 illustrates an example of a method of manufacturing the semiconductor module 300.

FIG. 15 shows positions of the connecting portions 172 versus a temperature at the connecting portions 172.

FIG. 16 shows a temperature of the connecting portions 172 versus a power cycle tolerance.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

Unless otherwise stated, the SI unit system is used as a unit system herein. Although a unit of length may be expressed in cm, calculations may be carried out after conversion to meters (m). In the present specification, one side of a direction parallel to a depth direction of a semiconductor substrate is referred to as “upper”, and the other side is referred to as “lower”. One of two main surfaces of a substrate, a layer, or other members is referred to as an “upper surface”, and the other surface is referred to as a “lower surface”. “Upper” and “lower” directions are not limited to a direction of gravity, or a direction in which a semiconductor device is mounted.

As used herein, technical matters may be described with orthogonal coordinate axes consisting of an X axis, a Y axis, and a Z axis. The orthogonal coordinate axes are merely for specifying relative positions of components, and are thus not for limiting to a specific direction. For example, the Z axis is not limited to represent a height direction with respect to the ground. Note that a +Z axis direction and a −Z axis direction are directions opposite to each other. When a direction is referred to as a “Z axis direction” without these “+” and “−” signs, it means the Z axis direction is parallel to +Z and −Z axes.

In the present specification, orthogonal axes parallel to an upper surface and lower surface of a semiconductor substrate are referred to as the X axis and the Y axis. Further, an axis perpendicular to the upper surface and the lower surface of the semiconductor substrate is referred to as the Z axis. As used herein, a direction of the Z axis may be referred to as a depth direction. Further, in the present specification, a direction parallel to the upper surface and the lower surface of the semiconductor substrate may be referred to as a horizontal direction, including the X axis direction and the Y axis direction. In the present specification, an upper surface side of the semiconductor substrate refers to a region from the center to the upper surface of the semiconductor substrate in the depth direction. A lower surface side of the semiconductor substrate refers to a region from the center to the lower surface of the semiconductor substrate in the depth direction.

As used herein, phrases such as “same” or “equal” may be used even when there is an error caused due to a variation in a fabrication step or the like. This error is within a range of 10% or less, for example. As used herein, references to directions such as “perpendicular,” “parallel,” or “along” may be used even when there is an error caused due to a variation in a fabrication step or the like. This error is within a range of 5 degrees or less, for example.

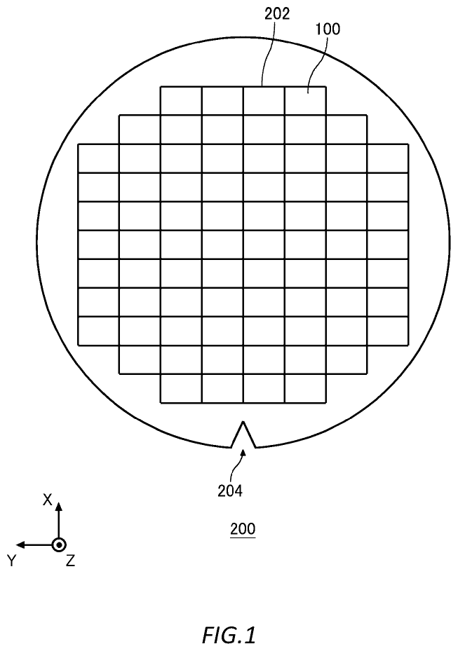

FIG. 1 shows a top view illustrating an example of a semiconductor wafer 200. The semiconductor wafer 200 is a plate-shaped substrate formed of a semiconductor material such as silicon or a compound semiconductor. The semiconductor wafer 200 is disk-shaped, for example. A plurality of semiconductor devices 100 is formed on the semiconductor wafer 200. The semiconductor wafer 200 is cut along dicing lines 202 in the semiconductor wafer 200, so that each semiconductor device 100 can be cut out. The semiconductor wafer 200 may be provided with a reference portion 204 that indicates a reference position in the semiconductor wafer 200. The reference portion 204 is, for example, a notch formed by notching an edge of the semiconductor wafer 200.

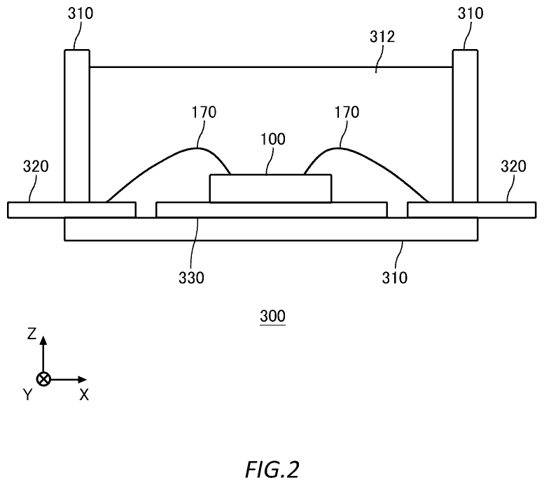

FIG. 2 shows a cross-sectional view illustrating an example of a semiconductor module 300 according to one embodiment of the present invention. The semiconductor module 300 includes a case portion 310, one or more semiconductor devices 100, an external interconnection 320, an internal interconnection 330, and a wire 170. The case portion 310 is formed of an insulative material such as resin or ceramic, and contains the one or more semiconductor devices 100, the internal interconnection 330, and the wire 170. The case portion 310 may be provided therein with a sealing portion 312 to cover the semiconductor devices 100, the internal interconnection 330, and the wire 170. The sealing portion 312 is, for example, formed of an insulative material such as silicone gel. The case portion 310 may include a heat-dissipation portion for dissipating heat inside the case portion 310 to outside. The heat-dissipation portion is, for example, a metal plate exposed from the case portion 310.

The internal interconnection 330 and the external interconnection 320 are parts of an electrical circuit. The internal interconnection 330 and the external interconnection 320 may be electrically connected to each other. The electrical circuit provided in the semiconductor module 300 may include other electrical elements. The internal interconnection 330 is provided inside the case portion 310. The external interconnection 320 electrically connects the inside and the outside of the case portion 310.

The semiconductor devices 100 are electrically connected to the electrical circuit provided inside the semiconductor module 300. Each of the semiconductor devices 100 of the present example is electrically connected to at least one of the internal interconnection 330 or the external interconnection 320. The example in FIG. 2 shows an electrode, provided on an upper surface of the semiconductor devices 100, and the external interconnection 320 that are electrically connected by the wire 170.

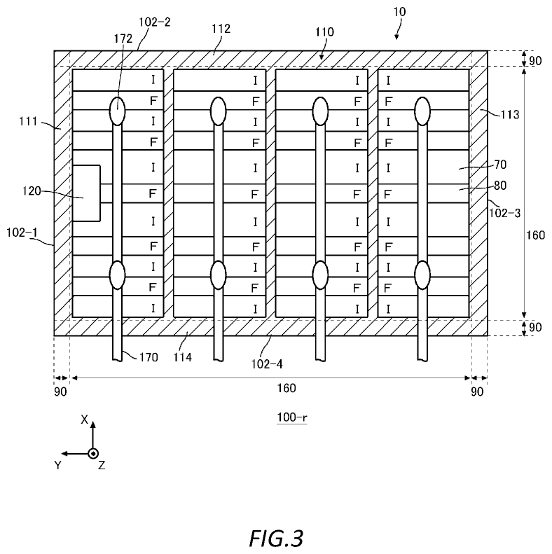

FIG. 3 illustrates an example of an upper surface structure of a semiconductor device 100-r according to a reference example. In the present specification, the semiconductor device 100-r may be simply referred to as a semiconductor device 100. The illustrated semiconductor device 100 of the present example is cut out from the semiconductor wafer 200 and mounted on the semiconductor module 300.

The semiconductor device 100 includes a semiconductor substrate 10. The semiconductor substrate 10 is a substrate formed of a semiconductor material such as silicon or a compound semiconductor. As an example, the semiconductor substrate 10 is a silicon substrate.

FIG. 3 shows positions of components of the semiconductor device 100 that are projected on an upper surface of the semiconductor substrate 10. FIG. 3 shows only some of the components of the semiconductor device 100, and does not show the other components. When merely referred to as the top view in the present specification, it means that the semiconductor substrate 10 is viewed from an upper surface side. In a top view, as described above, the positions of the respective components may be projected on the upper surface of the semiconductor substrate 10.

In the top view, the semiconductor substrate 10 includes end sides 102. The semiconductor substrate 10 of the present example includes, in the top view, two sets of the end sides 102 facing each other (a pair of the end sides 102-1 and 102-3, and a pair of the end sides 102-2 and 102-4). In FIG. 3, each of an X axis and a Y axis is parallel to either of the end sides 102. In addition, the Z axis is perpendicular to the upper surface of the semiconductor substrate 10.

The semiconductor substrate 10 is provided with an active section 160. A main current flows through the active section 160 when the semiconductor device 100 operates. The semiconductor device 100 may be a vertical device in which the main current flows in a depth direction between the upper surface and a lower surface of the semiconductor substrate 10, or may be a horizontal device in which the main current flows in a horizontal direction substantially parallel to the upper surface of the semiconductor substrate 10. The semiconductor device 100 of the present example is the vertical device. FIG. 3 does not show an upper surface electrode, such as an emitter electrode, provided above the active section 160 of the present example.

The active section 160 is provided with one or more transistor portions 70 including a transistor element such as an IGBT, and one or more diode portions 80 including a diode element such as an FWD. In the top view, the transistor portions 70 and the diode portions 80 are provided at different positions. In the example in FIG. 3, each of the transistor portions 70 and each of the diode portions 80 are arranged alternately along a predetermined first direction (an X axis direction in the present example) on the upper surface of the semiconductor substrate 10. The semiconductor device 100 of the present example is a reverse conducting IGBT (RC-IGBT).

In FIG. 3, regions in which the transistor portions 70 are arranged are marked with a symbol “|”, and regions in which the diode portions 80 are arranged are marked with a symbol “F”. The transistor portions 70 and the diode portions 80 of the present example may each have a longitudinal dimension in a Y axis direction. In other words, each of the transistor portions 70 has a length in the Y axis direction larger than a width in the X axis direction. Similarly, each of the diode portions 80 has a length in the Y axis direction larger than a width in the X axis direction.

Each of the diode portions 80 includes a cathode region of an N+ type in a region in contact with the lower surface of the semiconductor substrate 10. In the present specification, each of the diode portions 80 refers to a region where the cathode region is provided. In other words, each of the diode portions 80 is a region that overlaps with the cathode region in the top view. In a region other than the cathode region on the lower surface of the semiconductor substrate 10, a P+ type collector region may be provided.

Each of the transistor portions 70 includes the collector region of the P+ type in a region in contact with the lower surface of the semiconductor substrate 10. Further, in each of the transistor portions 70, an emitter region of the N type, a base region of the P type, and a gate structure having a gate conductive portion and a gate dielectric film are periodically arranged on the upper surface side of the semiconductor substrate 10.

The semiconductor device 100 may have one or more pads above the semiconductor substrate 10. The semiconductor device 100 of the present example includes a gate pad 120. Each pad is arranged in the vicinity of the end side 102. The vicinity of the end side 102 refers to a region between the end side 102 and the emitter electrode in the top view. When the semiconductor device 100 is mounted, each pad is connected to an electrical circuit different from the semiconductor device 100 via an interconnection such as a wire.

A gate potential is applied to the gate pad 120. The gate pad 120 is electrically connected to a conductive portion in a gate trench portion, which will be described later. The semiconductor device 100 includes a gate runner that connects the gate pad 120 and the gate trench portion. The gate runner is provided so as to encircle the active section 160. The gate runner may be arranged across the active section 160.

The semiconductor device 100 of the present example includes an edge termination structure 90 between the active section 160 and the end sides 102 in the top view. The edge termination structure 90 relaxes electric field concentration on the upper surface side of the semiconductor substrate 10. The edge termination structure 90 may include at least one of a guard ring, a field plate, or a RESURF that is annularly provided encircling the active section 160.

A protective film 110 is provided above the semiconductor substrate 10 to partially cover the semiconductor substrate 10. FIG. 3 shows the protective film 110 hatched with oblique lines. The protective film 110 is formed of an insulative material such as polyimide. The protective film 110 may be arranged so as to cover the edge termination structure 90. The protective film 110 may be arranged so as to further cover the gate runner described above. The protective film 110 shown in FIG. 3 includes a part covering the edge termination structure 90 and the gate runner that are arranged between the active section 160 and the end sides 102. The protective film 110 of the present example includes a first extending portion 111, a second extending portion 112, a third extending portion 113, and a fourth extending portion 114. The protective film 110 may further include a part covering the gate runner arranged across the active section 160.

The first extending portion 111 extends in the first direction (the X axis direction). That is, the first extending portion 111 has a longitudinal dimension in the first direction. The first extending portion 111 is arranged between the end side 102-1, parallel to the X axis direction, and the active section 160. The first extending portion 111 may be arranged also above the active section 160.

The second extending portion 112 extends in a second direction (the Y axis direction in the present example) which is different from the first direction. In other words, the second extending portion 112 has a longitudinal dimension in the second direction. The second extending portion 112 is arranged between the end side 102-2, parallel to the Y axis direction, and the active section 160. The second extending portion 112 may be arranged also above the active section 160.

The third extending portion 113 extends in the first direction (the X axis direction). That is, the third extending portion 113 has a longitudinal dimension in the first direction. The third extending portion 113 is arranged to face the first extending portion 111 in the Y axis direction. The third extending portion 113 is arranged between the end side 102-3, opposite to the end side 102-1, and the active section 160. The third extending portion 113 may be arranged also above the active section 160.

The fourth extending portion 114 extends in the second direction (the Y axis direction). That is, the fourth extending portion 114 has a longitudinal dimension in the second direction. The fourth extending portion 114 is arranged to face the second extending portion 112 in the X axis direction. The fourth extending portion 114 is arranged between the end side 102-4, opposite to the end side 102-2, and the active section 160. The fourth extending portion 114 may be arranged also above the active section 160.

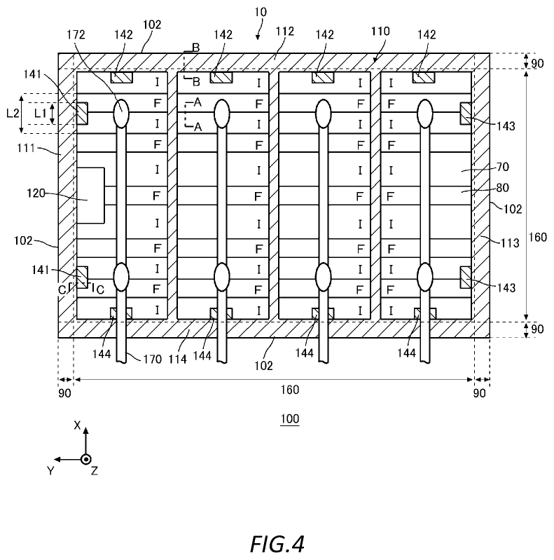

The wire 170 is connected to an upper surface of the emitter electrode (see FIG. 4, etc.) of the semiconductor device 100. Regions in which the wire 170 is in contact with the upper surface of the emitter electrode are referred to as connecting portions 172. The wire 170 may be crimped to the emitter electrode, or may be secured by a securing material such as solder. When the wire 170 is secured by the securing material, the connecting portions 172 are regions in which the securing material and the wire 170 are in contact with the emitter electrode. The connecting portions 172 are preferably arranged at positions where reliability of the connection to the emitter electrode is not deteriorated.

When the semiconductor device 100 is implemented in a circuit such as an inverter, the transistor portions 70 and the diode portions 80 alternately operate (that is, the main current flows alternately). The transistor portions 70 mainly generate heat when the transistor portions 70 are operating, and the diode portions 80 mainly generate heat when the diode portions 80 are operating.

Depending on operating conditions of the circuit, operating time of either ones of the transistor portions 70 or the diode portions 80 may become longer, and the heat generated in the ones of the portions may become larger. In such a case, when the connecting portions 172 are arranged only above the ones of the portions, repetition of ON operations and OFF operations in the transistor portions 70 and the diode portions 80 may deteriorate the reliability of the connection of the wire 170 to the emitter electrode. In other words, the power cycle tolerance can deteriorate.

In order to suppress the deterioration of the reliability of the connection described above, as shown in FIG. 3, each of the connecting portions 172 may be arranged so as to rest on both one of the transistor portions 70 and one of the diode portions 80. Such an arrangement of the connecting portions 172 can uniform heat generation in a vicinity of each of the connecting portions 172 independently of an operating state of the semiconductor device 100. However, because the transistor portions 70 and the diode portions 80 are covered with the emitter electrode formed of metal such as aluminum, it is difficult to detect, from above the emitter electrode, positions of the one of the transistor portions 70 and the one of the diode portions 80. Therefore, it is difficult to inspect a position at which each of the connecting portions 172 is arranged with respect to the one of the transistor portions 70 and the one of the diode portions 80 after the wire 170 is connected to the semiconductor device 100.

FIG. 4 illustrates an example of an upper surface structure of a semiconductor device 100 according to one embodiment of the present invention. The semiconductor device 100 of the present example includes first mark portions 141 in addition to the structure of the semiconductor device 100-r described with reference to FIG. 3. The semiconductor device 100 of the present example may further include at least ones of second mark portions 142, third mark portions 143, or fourth mark portions 144. The structure other than those is similar to that of the semiconductor device 100-r. One or more first mark portions 141, one or more second mark portions 142, one or more third mark portions 143, and one or more fourth mark portions 144 may be provided. Each of the mark portions defines a position at which each of connecting portions 172 is to be arranged. Each of the mark portions has a concave shape or a convex shape in the top view or in a depth direction of a semiconductor substrate 10.

Each of the first mark portions 141 is arranged upper than an upper surface electrode such as an emitter electrode to overlap both one of one or more transistor portions 70 and one of one or more diode portions 80 in the top view. The first mark portions 141 of the present example have a convex shape in the top view. In other words, the first mark portions 141 of the present example are in contact with a member arranged upper than the upper surface electrode, and protrude from the member in either direction within the top view.

The first mark portions 141 of the present example are provided in a protective film 110. The first mark portions 141 may be formed of a same material as the protective film 110. The first mark portions 141 of the present example protrude in a direction opposite to a second direction (in the present example, a negative direction of the Y axis) from a first extending portion 111 extending in a first direction. In the present example, the first direction is the X axis direction and the second direction is the Y axis direction. That is, the first mark portions 141 protrude from the first extending portion 111 in a direction orthogonal to an extending direction of the first extending portion 111. The first mark portions 141 may protrude from the first extending portion 111 toward an inside of an active section 160.

Each of the first mark portions 141 defines a position at which each of the connecting portions 172 is to be provided in the X axis direction. The first mark portions 141 and the connecting portions 172 may be arranged facing each other in the Y axis direction, respectively. The first mark portions 141 of the present example protrude from the first extending portion 111 toward the connecting portions 172. The first mark portions 141 and the connecting portions 172 are arranged apart from each other, respectively, in the top view. When the connecting portions 172 are arranged at a plurality of positions in the X axis direction, the first mark portions 141 may be provided for the respective connecting portions 172. The example in FIG. 4 shows the connecting portions 172 arranged at two positions in the X axis direction. The first mark portions 141 are provided for the respective connecting portions 172.

A length L1 of each of the first mark portions 141 in the X axis direction is smaller than a sum L2 of lengths of the one of the transistor portions 70 and the one of the diode portions 80 in the X axis direction. The length L2 is the sum of the lengths of the one of the transistor portions 70 and the one of the diode portions 80, the ones overlapping each of the first mark portions 141. Each of the first mark portions 141 neither overlaps two of the transistor portions 70 nor two of the diode portions 80. In other words, each of the first mark portions 141 straddles only one boundary line extending in the Y axis direction between the transistor portions 70 and the diode portions 80. The length L1 may be larger or smaller than the length in the X axis direction of the one of the transistor portions 70 that overlaps each of the first mark portions 141. The length L1 may be larger or smaller than the length in the X axis direction of the one of the diode portions 80 that overlaps each of the first mark portions 141. Providing each of the first mark portions 141 can define a position at which each of the connecting portions 172 is to be provided in the X axis direction.

Each of the second mark portions 142 is arranged upper than the upper surface electrode such as an emitter electrode to overlap either one portions of the transistor portions 70 or the diode portions 80 in the top view. The second mark portions 142 of the present example have a convex shape in the top view. In other words, the second mark portions 142 of the present example are in contact with a member arranged upper than the upper surface electrode, and protrude from the member in either direction within the top view.

The second mark portions 142 of the present example are provided in the protective film 110. The second mark portions 142 may be formed of a same material as the protective film 110. The second mark portions 142 of the present example protrude in the first direction from the second extending portion 112 extending in the second direction. The second mark portions 142 protrude from the second extending portion 112 in a direction orthogonal to an extending direction of the second extending portion 112. The second mark portions 142 may protrude from the second extending portion 112 toward the inside of the active section 160.

Each of the second mark portions 142 defines a position at which each of the connecting portions 172 is to be provided in the Y axis direction. The second mark portions 142 and the connecting portions 172 may be arranged facing each other in the X axis direction, respectively. The second mark portions 142 of the present example protrude from the second extending portion 112 toward the connecting portions 172. The second mark portions 142 and the connecting portions 172 are arranged apart from each other, respectively, in the top view. When the connecting portions 172 are arranged at a plurality of positions in the Y axis direction, the second mark portions 142 may be provided for respective connecting portions 172. The example in FIG. 4 shows the connecting portions 172 arranged at four positions in the Y axis direction. The second mark portions 142 are provided for respective connecting portions 172.

The second mark portions 142 of the present example are arranged so as to overlap the transistor portions 70. When an end of the active section 160 in the X axis direction is assigned to the diode portions 80, the second mark portions 142 are arranged so as to overlap the diode portions 80. A length of each one of the second mark portions 142 in the X axis direction is shorter than a length in the X axis direction of one of the transistor portions 70 that overlaps the one of the second mark portions 142, or shorter than a length in the X axis direction of one of the diode portions 80 that overlaps the one of the second mark portions 142. In other words, each of the second mark portions 142 may not overlap a boundary line extending in the Y axis direction between the transistor portions 70 and the diode portions 80. Providing each of the second mark portions 142 can define a position at which each of the connecting portions 172 is to be provided in the Y axis direction.

The third mark portions 143 have same arrangement and structure as the first mark portions 141, except for being provided on the third extending portion 113. The first mark portions 141 and the third mark portions 143 may be arranged facing each other in the Y axis direction, respectively. Each of the connecting portions 172 may be arranged at a position sandwiched between one of the first mark portions 141 and one of the third mark portions 143, the ones facing each other in the Y axis direction. Further providing each of the third mark portions 143 can more accurately define a position at which each of the connecting portions 172 is to be provided in the X axis direction.

The fourth mark portions 144 have same arrangement and structure as the second mark portions 142, except for being provided on the fourth extending portion 114. The second mark portions 142 and the fourth mark portions 144 may be arranged facing each other in the X axis direction, respectively. Each of the connecting portions 172 may be arranged at a position sandwiched between one of the second mark portions 142 and one of the fourth mark portions 144, the ones facing each other in the X axis direction. Further providing each of the fourth mark portions 144 can more accurately define a position at which each of the connecting portions 172 is to be provided in the Y axis direction.

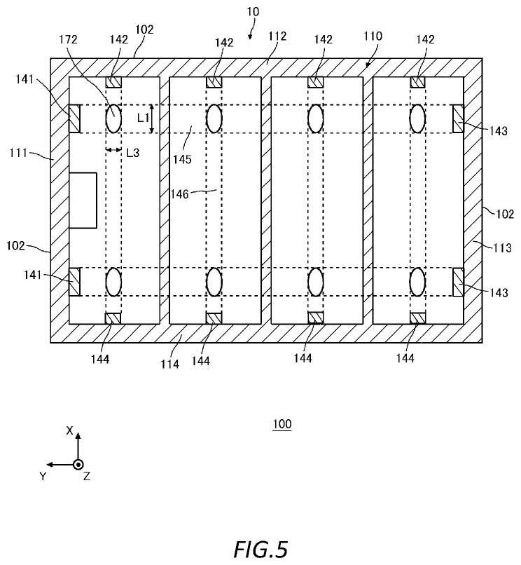

FIG. 5 illustrates an arrangement example of mark portions and connecting portions 172. FIG. 5 does not show some members shown in FIG. 4. Arrangement of a protective film 110, the mark portions, and the connecting portions 172 is similar to the example in FIG. 4.

As described above, at least one of the connecting portions 172 is sandwiched between one of the first mark portions 141 and one of the third mark portions 143 and sandwiched between one of the second mark portions 142 and one of the fourth mark portions 144. Every one of the connecting portions 172 may be sandwiched between one of the first mark portions 141 and one of the third mark portions 143 and sandwiched between one of the second mark portions 142 and one of the fourth mark portions 144.

Regions sandwiched between the first mark portions 141 and the third mark portions 143 are referred to as regions 145, respectively, and regions sandwiched between the second mark portions 142 and the fourth mark portions 144 are referred to as regions 146, respectively. Each of the connecting portions 172 may be arranged in a region where one of the regions 145 and one of the regions 146 overlap. In the region, at least part of each of the connecting portions 172, at least a center (or a gravity center) of each of the connecting portions 172, half or more of an area of each of the connecting portions 172, or whole of each of the connecting portions 172 may be arranged.

A length L1 of the first mark portions 141 and the third mark portions 143 in the X axis direction and a length L3 of the second mark portions 142 and the fourth mark portions 144 in the Y axis direction may be determined depending on a shape of the connecting portions 172. The connecting portions 172 of the present example have a longer dimension in the X axis direction and a shorter dimension in the Y axis direction. The length L1 may be greater than the length L3. The length L1 may be a same as a length of the connecting portions 172 in the X axis direction. The length L3 may be a same as a length of the connecting portions 172 in the Y axis direction.

As described with reference to FIGS. 4 and 5, providing each of the mark portions in the semiconductor device 100 can accurately define a position at which each of the connecting portions 172 is to be arranged. Each of the mark portions may be formed in a state of the semiconductor wafer 200 as shown in FIG. 1. The semiconductor wafer 200 has a marker formed therein to define a position in a plane of the semiconductor wafer 200. For example, the dicing lines 202 are provided with a marker that is not covered with an upper surface electrode such as an emitter electrode. Each of the mark portions is formed based on a position of the marker, so that each of the mark portions can be accurately provided at a predetermined position on a semiconductor substrate 10. Therefore, when the wire 170 is connected to the semiconductor device 100 cut out from the semiconductor wafer 200, it is possible to accurately check that each of the connecting portions 172 is arranged at a predetermined position using each of the mark portions. In addition, a position at which the wire 170 is connected to the semiconductor device 100 is controlled using a position of each of the mark portions, so that a position of each of the connecting portions 172 can be accurately controlled.

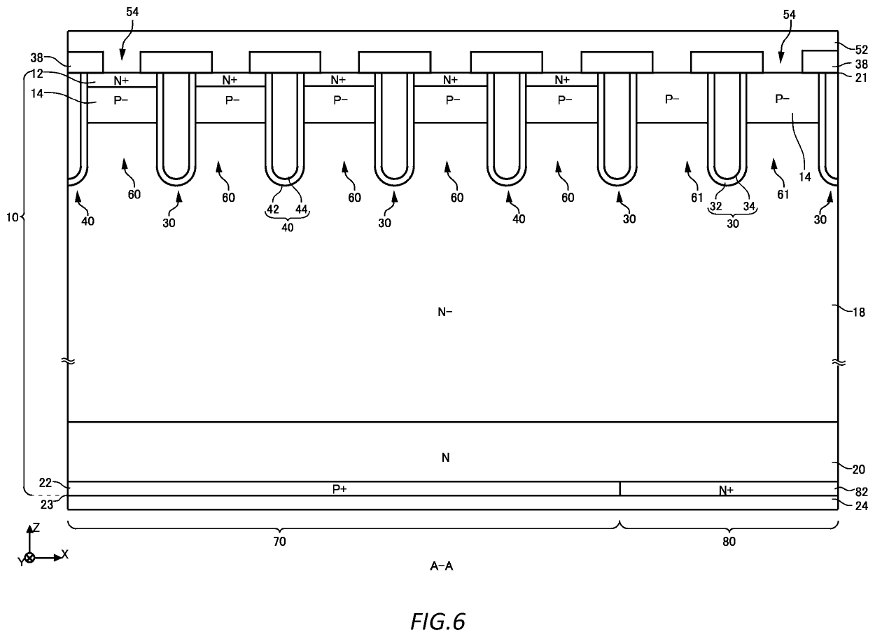

FIG. 6 illustrates an example of a cross section taken along A-A in FIG. 4. The A-A cross section is an XZ plane passing through part of the transistor portions 70 and part of the diode portions 80. The semiconductor device 100 of the present example includes the semiconductor substrate 10, an interlayer dielectric film 38, an emitter electrode 52, and a collector electrode 24 in the cross section. The emitter electrode 52 is an example of the upper surface electrode. The emitter electrode 52 and the collector electrode 24 are formed of a metal material such as aluminum.

The interlayer dielectric film 38 is provided in an upper surface 21 of the semiconductor substrate 10. The interlayer dielectric film 38 is a film including at least one layer of a dielectric film such as silicate glass added with impurities of boron, phosphorus, or the like, a thermally oxidized film, or other dielectric films. The interlayer dielectric film 38 has a contact hole 54 provided therein.

The emitter electrode 52 is provided above the interlayer dielectric film 38. The emitter electrode 52 is in contact with an upper surface 21 of the semiconductor substrate 10 through the contact hole 54 of the interlayer dielectric film 38. The collector electrode 24 is provided on the lower surface 23 of the semiconductor substrate 10. In the present specification, a direction between the emitter electrode 52 and the collector electrode 24 (the Z axis direction) is referred to as the depth direction.

The semiconductor substrate 10 includes an N− type drift region 18. The drift region 18 is provided in each of the transistor portions 70 and the diode portions 80. The upper surface 21 of the semiconductor substrate 10 has a plurality of trench portions provided therein. The plurality of trench portions includes a gate trench portion 40 connected to a gate runner, and a dummy trench portion 30 connected to the emitter electrode 52. The plurality of trench portions is arranged side by side in the X axis direction. Each of the trench portions is provided to extend in the Y axis direction. As an example, each of the transistor portions 70 has the gate trench portion 40 and the dummy trench portion 30 arranged therein. As an example, each of the diode portions 80 has the dummy trench portion 30 arranged therein and does not have the gate trench portion 40 arranged therein.

The gate trench portion 40 includes a gate trench, a gate dielectric film 42, and a gate conductive portion 44 provided on the upper surface 21 of the semiconductor substrate 10. The gate dielectric film 42 is provided to cover the inner wall of the gate trench. The gate dielectric film 42 may be formed by oxidizing or nitriding a semiconductor on the inner wall of the gate trench. The gate conductive portion 44 is provided farther inward than the gate dielectric film 42 inside the gate trench. That is, the gate dielectric film 42 insulates the gate conductive portion 44 from the semiconductor substrate 10. The gate conductive portion 44 is formed of a conductive material such as polysilicon.

The gate conductive portion 44 may be provided longer than the base region 14 in the depth direction. The gate trench portion 40 in the cross section is covered by the interlayer dielectric film 38 on the upper surface 21 of the semiconductor substrate 10. The gate conductive portion 44 is electrically connected to the gate runner. When a predetermined gate voltage is applied to the gate conductive portion 44, a channel is formed by an electron inversion layer in a surface layer of the base region 14 at a boundary in contact with the gate trench portion 40.

The dummy trench portion 30 may have the same structure as the gate trench portion 40 in the cross section. The dummy trench portion 30 has a dummy trench, a dummy dielectric film 32, and a dummy conductive portion 34 provided on the upper surface 21 of the semiconductor substrate 10. The dummy conductive portion 34 is electrically connected to the emitter electrode 52. The dummy dielectric film 32 is provided to cover an inner wall of the dummy trench. The dummy conductive portion 34 is provided inside the dummy trench and is provided farther inward than the dummy dielectric film 32. The dummy dielectric film 32 insulates the dummy conductive portion 34 from the semiconductor substrate 10. The dummy conductive portion 34 may be formed of the same material as the gate conductive portion 44. For example, the dummy conductive portion 34 is formed of a conductive material such as polysilicon. The dummy conductive portion 34 may have the same length as the gate conductive portion 44 in the depth direction.

The gate trench portion 40 and the dummy trench portion 30 of the present example are covered with the interlayer dielectric film 38 on the upper surface 21 of the semiconductor substrate 10. However, the gate conductive portion 44 of the gate trench portion 40 is connected to the gate runner via the contact hole provided in the interlayer dielectric film 38. In addition, the dummy conductive portion 34 of the dummy trench portion 30 is connected to the emitter electrode 52 via the contact hole provided in the interlayer dielectric film 38.

A part sandwiched between two of the trench portions arranged side by side in the X axis direction is referred to as a mesa portion. A mesa portion 60 is provided in the transistor portions 70 and a mesa portion 61 is provided in the diode portions 80.

In the mesa portion 60 of the transistor portions 70, an N+ type of emitter region 12 and a P− type of base region 14 are provided in order from an upper surface 21 side of the semiconductor substrate 10. The drift region 18 is provided below the base region 14. The mesa portion 60 may be provided with an N+ type accumulation region. The accumulation region is arranged between the base region 14 and the drift region 18. The accumulation region being provided can enhance a carrier injection enhancement effect (IE effect) to decrease an ON voltage. The accumulation region may be provided to cover an entire lower surface of the base region 14 in each mesa portion 60.

The emitter region 12 is exposed on the upper surface 21 of the semiconductor substrate 10 and is provided in contact with gate trench portion 40. The emitter region 12 may be in contact with the trench portions on both sides of the mesa portion 60. The emitter region 12 has a higher doping concentration than the drift region 18.

The base region 14 is provided below the emitter region 12. The base region 14 of the present example is provided in contact with the emitter region 12. The base region 14 may be in contact with the trench portions on both sides of the mesa portion 60.

The mesa portion 61 of the diode portions 80 is provided with the P− type of base region 14 in contact with the upper surface 21 of the semiconductor substrate 10. The drift region 18 is provided below the base region 14. In the mesa portion 61, the accumulation region may be provided below the base region 14.

In each of the transistor portions 70 and the diode portions 80, an N+ type buffer region 20 may be provided below the drift region 18. The doping concentration of the buffer region 20 is higher than the doping concentration of the drift region 18. The buffer region 20 may function as a field stopper layer which prevents a depletion layer expanding from the lower end of the base region 14 from reaching the collector region of the P+ type 22 and the cathode region 82 of the N+ type.

In the transistor portions 70, the collector region of the P+ type 22 is provided below the buffer region 20. An acceptor concentration of the collector region 22 is higher than an acceptor concentration of the base region 14.

Below the buffer region 20 in the diode portions 80, the cathode region 82 of the N+ type is provided. A donor concentration of the cathode region 82 is higher than a donor concentration of the drift region 18. The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10.

A boundary position between the collector region 22 and the cathode region 82 in the X axis direction is defined as a boundary position between one of the transistor portions 70 and one of the diode portions 80. As described with reference to FIG. 4, each of the first mark portions 141 and each of the third mark portions 143 are arranged so as to overlap the boundary position between the collector region 22 and the cathode region 82.

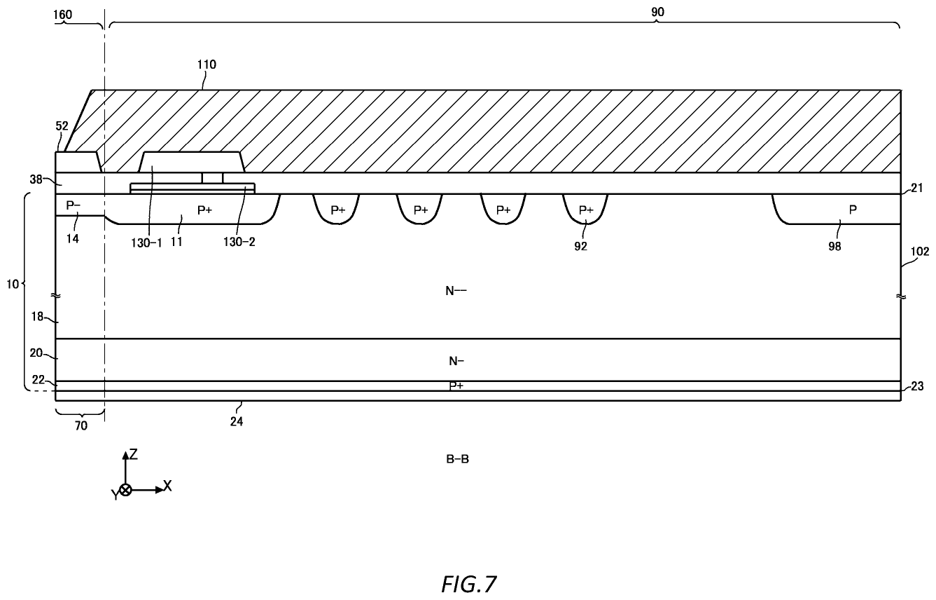

FIG. 7 illustrates an example of a cross section taken along B-B in FIG. 4. The B-B cross section is an XZ plane passing through the protective film 110 and an edge termination structure 90. FIG. 7 shows a cross section passing through the second extending portion 112 of the protective film 110, but the semiconductor device 100 has a similar structure in cross sections passing through other extending portions of the protective film 110. FIG. 7 also shows part of the transistor portions 70 in a vicinity of the edge termination structure 90.

In the present example, a region from an end side 102 of the semiconductor substrate 10 to gate runners 130 is defined as the edge termination structure 90. Each of the gate runners 130 is an interconnection connected to a gate pad 120. Each of the gate runners 130 is arranged above the upper surface 21 of the semiconductor substrate 10. The gate runners 130 are provided so as to encircle the active section 160 in the top view.

In the present example, a gate runner 130-1 and a gate runner 130-2 are arranged to be stacked in the Z axis direction. The gate runner 130-1 is formed of a metal material such as aluminum, and the gate runner 130-2 is formed of polysilicon added with impurities.

The gate runner 130-2 and the semiconductor substrate 10 are insulated by a dielectric film such as a thermally oxidized film. The gate runner 130-2 is connected to the gate conductive portion 44 at some position different from the cross section shown in FIG. 7.

The gate runner 130-1 is arranged above the gate runner 130-2. An interlayer dielectric film 38 is arranged between the gate runner 130-1 and the gate runner 130-2. The interlayer dielectric film 38 has a contact hole provided therein for connecting the gate runner 130-1 and the gate runner 130-2.

The semiconductor substrate 10 below the gate runners 130 has a well region 11 provided therein. The well region 11 may be provided so as to encircle the active section 160 in the top view. The well region 11 is provided from the upper surface 21 of the semiconductor substrate 10 to a position deeper than the base region 14. The well region 11 is exposed on the upper surface 21. The well region 11 may be electrically connected to the emitter electrode 52. A region from the end side 102 of the semiconductor substrate 10 to the well region 11 may be defined as the edge termination structure 90.

The edge termination structure 90 includes one or more guard rings 92. The edge termination structure 90 may further include field plates arranged above each of the guard rings 92. The edge termination structure 90 of the present example further includes a channel stopper 98.

The guard rings 92 are P+ type regions provided in contact with the upper surface 21 of semiconductor substrate 10. One or more of the guard rings 92 are provided between the well region 11 and the end side 102 of the semiconductor substrate 10, and exposed on the upper surface 21 of the semiconductor substrate 10. Each of the guard rings 92 encircles the active section 160.

The Channel stopper 98 is provided in contact with the upper surface 21 and the end side 102 of the semiconductor substrate 10. The channel stopper 98 is of P type having a concentration equal to or higher than that of the base region 14, or is of N type having a higher concentration than that of the drift region 18. A collector potential may be applied to the channel stopper 98. Potential of the channel stopper 98 equalized to the potential of the collector electrode 24 prevents a depletion layer extending from the active section 160 from reaching a side surface of the semiconductor substrate 10. This improves the breakdown voltage of the semiconductor device 100.

The protective film 110 may cover the entire edge termination structure 90. The protective film 110 may be provided from the end side 102 to an edge of the active section 160. The protective film 110 may cover the gate runners 130. The protective film 110 may cover the well region 11. The protective film 110 may cover part of the emitter electrode 52.

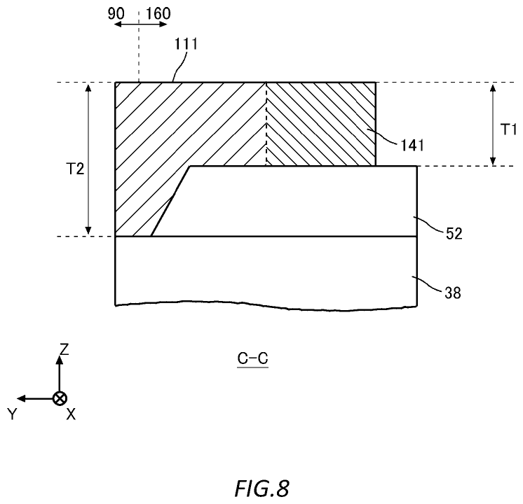

FIG. 8 illustrates an example of a cross section taken along C-C in FIG. 4. The C-C cross section is a YZ plane passing through the first extending portion 111 and one of the first mark portions 141. Other extending portions and other mark portions may also have a structure described with reference to FIG. 8.

The first extending portion 111 of the present example covers an edge of the emitter electrode 52. The first mark portions 141 are provided above the emitter electrode 52 so as to protrude in a direction opposite to the Y axis direction (that is, the negative direction of the Y axis) from the first extending portion 111. With respect to being above the emitter electrode 52, an upper end position of the first extending portion 111 may be a same as an upper end position of the first mark portions 141. An upper end position refers to a position of part arranged uppermost in the Z axis direction.

T1 denotes a thickness of the first mark portions 141 in the Z axis direction, and T2 denotes a thickness of the first extending portion 111 in the Z axis direction. The thickness T1 is a distance in the Z axis direction from a top of the emitter electrode 52 to a top of the first mark portions 141. The thickness T2 is a thickness of the first extending portion 111 where the first extending portion 111 does not overlap the emitter electrode 52. The thickness T2 may be a distance in the Z axis direction from a top of the interlayer dielectric film 38 to a top of the first extending portion 111.

The thickness T1 may be smaller than the thickness T2. Thickening the first extending portion 111 facilitates protecting the edge termination structure 90, the gate runners 130, and the like. The first mark portions 141 may not have a capability for protecting, and therefore the first mark portions 141 may be formed relatively thin. Thinning the first mark portions 141 can reduce a stress generated in the first mark portions 141. The protective film 110 including the first extending portion 111 and the first mark portions 141 is formed of an insulative material such as resin or polyimide. An adhesion strength between the protective film 110 and the emitter electrode 52 is lower than an adhesion strength between the protective film 110 and the interlayer dielectric film 38 (or the semiconductor substrate 10). Therefore, forming the first mark portions 141 thin can reduce the stress in the first mark portions 141 and prevent the first mark portions 141 from peeling off the emitter electrode 52.

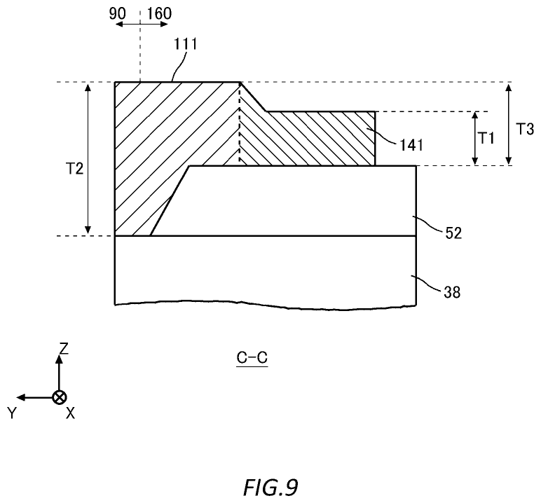

FIG. 9 illustrates another example of the cross section taken along line C-C. The C-C cross section is a YZ plane passing through a first extending portion 111 and one of first mark portions 141, and other extending portions and other mark portions may also have a structure described with reference to FIG. 9.

In the present example, an upper end position of the first mark portions 141 is lower than an upper end position of the first extending portion 111. The structure other than that is similar to the example shown in FIG. 8. In the present example, a thickness T1 of the first mark portions 141 is smaller than a thickness T3 of the first extending portion 111 above an emitter electrode 52. Such a configuration can further reduce a stress in the first mark portions 141 and prevent the first mark portions 141 from peeling off the emitter electrode 52. The thickness T1 may be 90% or less, 80% or less, 70% or less, or 50% or less of the thickness T3. The thickness T1 may be 10% or more of the thickness T3.

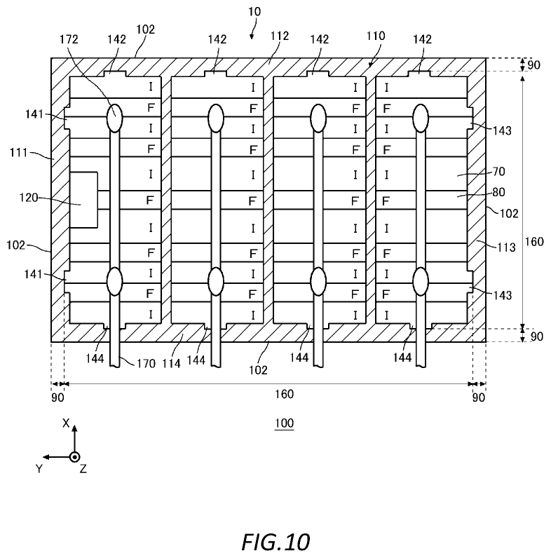

FIG. 10 illustrates another example of an upper surface structure of a semiconductor device 100. The semiconductor device 100 of the present example differs from the semiconductor device 100 described with reference to FIGS. 4 to 9 in a structure of each of mark portions. A structure of other parts may be similar to any of aspects described with reference to FIGS. 4 to 9.

Each of the mark portions in the present example has a concave shape in the top view. In other words, each of the mark portions in the present example is a part that is concave toward an inside of a member from an end side of the member, the member arranged upper than an upper surface electrode. Each of the mark portions may be a concave portion provided in each of extending portions of a protective film 110. Each of the mark portions is a concave portion formed in each of the extending portions of the protective film 110 from an end side closest to an active section 160 toward a side opposite to the active section 160. A position and a size of each of the mark portions may be similar to the examples described with reference to FIGS. 4 to 9. Each of the mark portions in the present example may be arranged in an area that does not overlap gate runners 130 or guard rings 92. Thereby, the gate runners 130 and the guard rings 92 can be covered to protect with the protective film 110. Each of the mark portions may be arranged above an emitter electrode 52. Each of the mark portions may be arranged within an area of the emitter electrode 52.

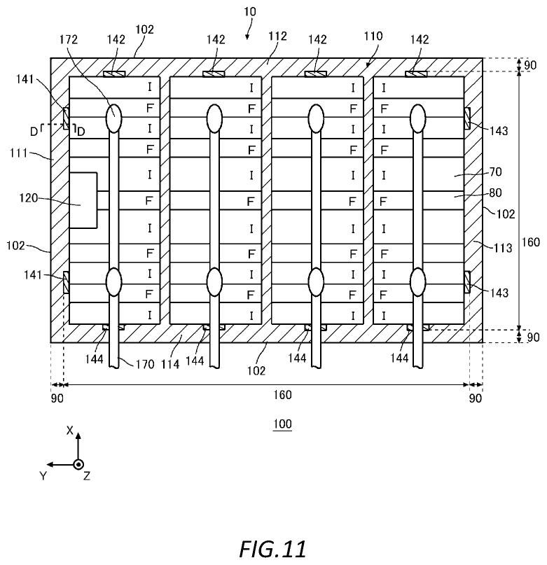

FIG. 11 illustrates another example of an upper surface structure of a semiconductor device 100. The semiconductor device 100 of the present example differs from the semiconductor device 100 described with reference to FIGS. 4 to 10 in a structure of each of mark portions. A structure of other parts may be similar to any of aspects described with reference to FIGS. 4 to 10.

Each of the mark portions in the present example has a concave shape or a convex shape in a Z axis direction. In other words, each of the mark portions in the present example is a concave portion or a convex portion provided on an upper surface of a member arranged upper than an upper surface electrode. Each of the mark portions may be provided on an upper surface of each of extending portions of a protective film 110. A position and a size of each of the mark portions may be similar to the examples described with reference to FIGS. 4 to 11.

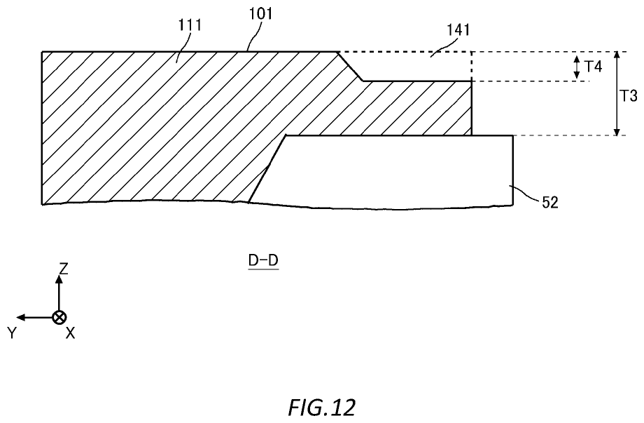

FIG. 12 illustrates an example of a cross section taken along line D-D in FIG. 11. The D-D cross section is a YZ plane passing through a first extending portion 111 and one of first mark portions 141, and other extending portions and other mark portions may also have a structure described with reference to FIG. 12.

Each of the first mark portions 141 of the present example is a concave portion depressed downward from an upper surface 101 of the first extending portion 111. However, the first extending portion 111 also extends below the first mark portions 141. That is, a thickness T4 of the first mark portions 141 (that is, a depth of the concave portion) is smaller than a thickness T3 of the first extending portion 111. The thickness T4 may be 10% or more, 20% or more, 30% or more, or 50% or more of the thickness T3. The thickness T4 may be 90% or less of the thickness T3. Each of the first mark portions 141 may be arranged in an area that does not overlap gate runners 130 or guard rings 92. Thereby, the gate runners 130 and the guard rings 92 can be covered to protect with the protective film 110. Each of the first mark portions 141 may be arranged above an emitter electrode 52. Each of the first mark portions 141 may be arranged within an area of the emitter electrode 52.

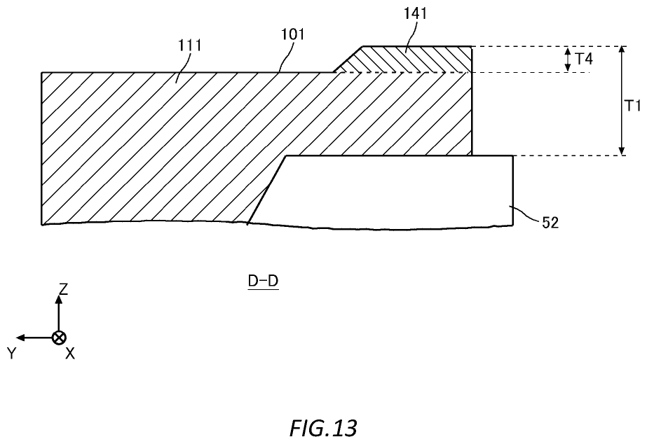

FIG. 13 illustrates another example of the cross section taken along line D-D in FIG. 11. The D-D cross section is a YZ plane passing through a first extending portion 111 and one of first mark portions 141, and other extending portions and other mark portions may also have a structure described with reference to FIG. 12.

Each of the first mark portions 141 of the present example is a convex portion that protrudes upward from an upper surface 101 of the first extending portion 111. A thickness T4 of the first mark portions 141 may be 10% or less, 20% or less, 30% or less, or 50% or less of a thickness T3. The thickness T4 may be 90% or more of the thickness T3. Each of the first mark portions 141 may or may not overlap gate runners 130 or guard rings 92.

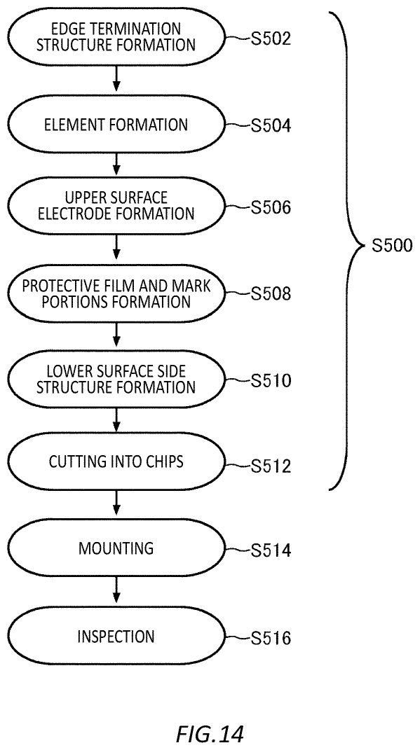

FIG. 14 illustrates an example of a method of manufacturing the semiconductor module 300. The method of manufacturing of the semiconductor module 300 includes a manufacturing step S500 of the semiconductor device 100, a mounting step S514, and am inspecting step S516.

In the manufacturing step S500 of the semiconductor device 100, the edge termination structure 90 is formed in each semiconductor device 100 of the semiconductor wafer 200 (S502). In addition, semiconductor elements such as the transistor portions 70 and the diode portions 80 are formed on an upper surface side of the semiconductor wafer 200 (S504). At S504, the trench portions, the emitter region 12 and the base region 14 may be formed.

Then, an upper surface electrode made of metal, such as the emitter electrode 52, the gate pad 120, and the gate runner 130-1, is formed above the semiconductor wafer 200 (S506). At S506, the gate runner 130-2, the interlayer dielectric film 38 and the contact hole may be formed before forming the upper surface electrode. The predetermined marker may be formed on the dicing lines 202 in steps S502 to S506. The marker may be formed of the interlayer dielectric film 38 or the like.

Then, the protective film 110, arranged upper than the upper surface electrode, and each of the mark portions (the first mark portions 141, the second mark portions 142, the third mark portions 143, and the fourth mark portions 144) are formed (S508). As shown in FIG. 8 and the like, the protective film 110 may include a part arranged lower than the upper surface electrode. The position of each of the mark portions may be controlled based on the position of the marker or the like provided in the semiconductor wafer 200. Thereby, the position of each of the mark portions can be accurately controlled.

Then, a structure on a lower surface side of the semiconductor wafer 200 is formed (S510). At S510, the buffer region 20, the collector region 22, the cathode region 82 and the collector electrode 24 described with reference to FIG. 5 and the like may be formed.

Then, the semiconductor wafer 200 is cut along the dicing lines 202 to be cut out into each semiconductor device 100 (S512). Thus, the semiconductor device 100 can be manufactured.

Then, the semiconductor device 100 is mounted on the semiconductor module 300 (S514). At S514, the wire 170 is connected to the upper surface electrode of the semiconductor device 100.

Then, it is inspected that each of the connecting portions 172 of the wire 170 is provided at the predetermined position (S516). At S516, an optical inspection device may automatically inspect that each of the connecting portions 172 is provided at the position defined by each of the mark portions. According to the present example, because each of the mark portions is provided upper than the emitter electrode 52, the position of each of the connecting portions 172 can be inspected easily and accurately.

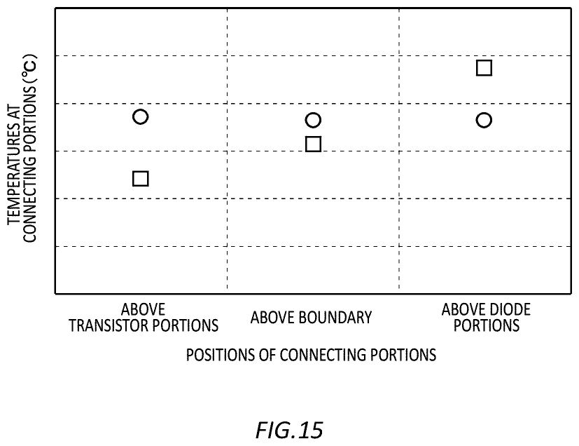

FIG. 15 shows positions of connecting portions 172 versus temperatures at the connecting portions 172. A horizontal axis in FIG. 15 indicates the connecting portions 172 arranged above the transistor portions 70, arranged above a boundary between the transistor portions 70 and the diode portions 80, and arranged above the diode portions 80. A vertical axis in FIG. 15 indicates the temperatures at the connecting portions 172. The vertical axis in FIG. 15 is a linear axis. In FIG. 15, circle symbols show results from temperature measurement while the main current flowed through the transistor portions 70, and square symbols show results from temperature measurement while the main current flowed through the diode portions 80.

As shown in FIG. 15, when the connecting portions 172 are arranged above the transistor portions 70 or the diode portions 80, the temperature at the connecting portions 172 changes depending on the operating state of the semiconductor device 100. On the other hand, when the connecting portions 172 are arranged above the boundary between the transistor portions 70 and the diode portions 80, the temperature at the connecting portions 172 hardly changes even if the operating state of the semiconductor device 100 changes. Therefore, the connecting portions 172 are arranged above the boundary between the transistor portions 70 and the diode portions 80, so that, even if the operating state of the semiconductor device 100 changes repeatedly, a temperature change at the connecting portions 172 can be suppressed to suppress generation of thermal stress at the connecting portions 172. Thus, the reliability of the connection of the connecting portions 172 can be improved.

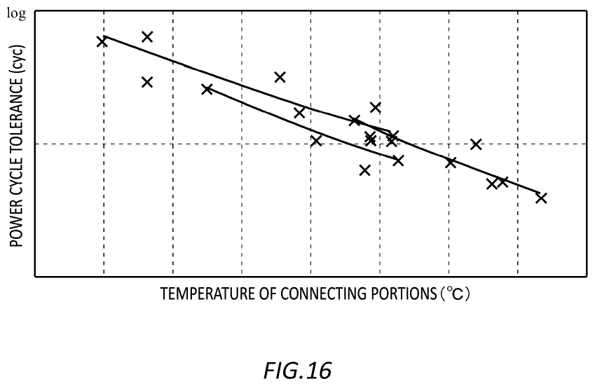

FIG. 16 shows a temperature of the connecting portions 172 versus a power cycle tolerance. In the example in FIG. 16, a temperature at the connecting portions 172 was repeatedly cycled between the temperature shown on a horizontal axis and a predetermined temperature. The power cycle tolerance on a vertical axis in FIG. 16 indicates a number of cycles of the temperature change at the connecting portions 172 when the connecting portions 172 were separated from the upper surface electrode. In FIG. 16, the vertical axis is a logarithmic axis, and the horizontal axis is a linear axis. As shown in FIG. 16, the power cycle tolerance has a correlation with the temperature of the connecting portions 172. The power cycle tolerance of the connecting portions 172 increases as a variation in the temperature at the connecting portions 172 decreases. The position of each of the connecting portions 172 is accurately defined using each of the mark portions, so that the variation in the temperature at the connecting portions 172 can be reduced to increase the power cycle tolerance of the connecting portions 172.

While the present invention has been described by way of the embodiments, the technical scope of the present invention is not limited to the above-described embodiments. It is apparent to persons skilled in the art that various alterations or improvements can be made to the above-described embodiments. It is also apparent from the description of the claims that embodiments added with such alterations or improvements can be included in the technical scope of the present invention.

The operations, procedures, steps, stages, or the like of each process performed by a device, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A semiconductor device comprising:
one or more transistor portions and one or more diode portions provided at different positions in a top view;
a semiconductor substrate provided with the one or more transistor portions and the one or more diode portions;
an upper surface electrode arranged above the semiconductor substrate; and
one or more first mark portions arranged upper than the upper surface electrode, each of the one or more first mark portions being arranged so as to overlap both one of the one or more transistor portions and one of the one or more diode portions in the top view, wherein
each of the one or more first mark portions has a concave shape or a convex shape in the top view or in a depth direction of the semiconductor substrate.

2. The semiconductor device according to claim 1, wherein
each of the one or more transistor portions and each of the one or more diode portions are arranged side by side alternately along a first direction in the top view, and
a length of each of the one or more first mark portions in the first direction is smaller than a sum of lengths of one of the one or more transistor portions and one of the one or more diode portions in the first direction.

3. The semiconductor device according to claim 1, further comprising:
a protective film arranged upper than the upper surface electrode, wherein
the one or more first mark portions are provided in the protective film.

4. The semiconductor device according to claim 3, wherein
each of the one or more transistor portions and each of the one or more diode portions are arranged side by side alternately along a first direction in the top view,
the protective film comprises a first extending portion extending along the first direction, and
the one or more first mark portions protrude from the first extending portion in a second direction different from the first direction in the top view.

5. The semiconductor device according to claim 4, wherein
an upper end position of the one or more first mark portions is lower than an upper end position of the first extending portion.

6. The semiconductor device according to claim 3, wherein
each of the one or more transistor portions and each of the one or more diode portions are arranged side by side alternately along a first direction in the top view,
the protective film comprises a first extending portion extending along the first direction, and
the one or more first mark portions protrude upward from the first extending portion.

7. The semiconductor device according to claim 3, wherein
each of the one or more transistor portions and each of the one or more diode portions are arranged side by side alternately along a first direction in the top view,
the protective film comprises:
a first extending portion extending along the first direction and provided with the one or more first mark portions; and
a second extending portion extending along a second direction different from the first direction in the top view, and
the semiconductor device further comprises one or more second mark portions provided on the second extending portion, wherein each of the one or more second mark portions has a concave shape or a convex shape in the top view or in a depth direction of the semiconductor substrate.

8. The semiconductor device according to claim 7, wherein
a length of the one or more first mark portions in the first direction is greater than a length of the one or more second mark portions in the second direction.

9. The semiconductor device according to claim 1, further comprising:
one or more third mark portions arranged upper than the upper surface electrode, each of the one or more third mark portions being arranged so as to overlap both one of the one or more transistor portions and one of the one or more diode portions in the top view, wherein
each of the one or more third mark portions has a concave shape or a convex shape in the top view or in a depth direction of the semiconductor substrate,
the one or more transistor portions and the one or more diode portions have a longitudinal dimension along a second direction in the top view, and
the one or more first mark portions and the one or more third mark portions are arranged facing each other in the second direction.

10. A semiconductor module comprising:
a semiconductor device;
an electrical circuit; and
a wire connecting the semiconductor device and the electrical circuit,
wherein
the semiconductor device comprises:
one or more transistor portions and one or more diode portions provided at different positions in a top view;
a semiconductor substrate provided with the one or more transistor portions and the one or more diode portions;
an upper surface electrode arranged above the semiconductor substrate and connected to the wire; and
one or more first mark portions arranged upper than the upper surface electrode, each of the one or more first mark portions being arranged so as to overlap both one of the one or more transistor portions and one of the one or more diode portions in the top view, wherein
each of the one or more first mark portions has a concave shape or a convex shape in the top view or in a depth direction of the semiconductor substrate.

11. The semiconductor module according to claim 10, wherein the semiconductor device further comprises:
one or more second mark portions arranged upper than the upper surface electrode, each of the one or more second mark portions being arranged so as to overlap both one of the one or more transistor portions and one of the one or more diode portions in the top view, wherein
each of the one or more second mark portions has a concave shape or a convex shape in the top view or in a depth direction of the semiconductor substrate,
each of the one or more transistor portions and each of the one or more diode portions are arranged side by side alternately along a first direction in the top view,
the one or more transistor portions and the one or more diode portions have a longitudinal dimension along a second direction in the top view, and
connecting portions at which the wire is connected to the upper surface electrode are arranged facing the one or more first mark portions in the second direction and are arranged facing the one or more second mark portions in the first direction.

12. The semiconductor module according to claim 10, wherein the semiconductor device further comprises:
one or more third mark portions arranged upper than the upper surface electrode, each of the one or more third mark portions being arranged so as to overlap both one of the one or more transistor portions and one of the one or more diode portions in the top view, wherein
each of the one or more third mark portions has a concave shape or a convex shape in the top view or in a depth direction of the semiconductor substrate, and
each of connecting portions at which the wire is connected to the upper surface electrode is sandwiched between one of the one or more first mark portions and one of the one or more third mark portions.

13. A method of manufacturing a semiconductor device comprising one or more transistor portions and one or more diode portions provided at different positions in a top view, comprising:
forming the one or more transistor portions and the one or more diode portions on a semiconductor substrate;
forming an upper surface electrode above the semiconductor substrate; and
forming one or more first mark portions arranged upper than the upper surface electrode, each of the one or more first mark portions being arranged so as to overlap both one of the one or more transistor portions and one of the one or more diode portions in the top view, wherein each of the one or more first mark portions has a concave shape or a convex shape in the top view or in a depth direction of the semiconductor substrate.
